(19) United States
(12) Patent Application Publication
(10) Pub. No.: US 2026/0305170 A1
(43) Pub. Date: Oct. 1, 2026

(54) Fixed-Footprint Thermoelectric Systems with Variable Junction Density

(71) Applicant: FAIZAN AHMED, San Jose, CA (US)

(72) Inventor: FAIZAN AHMED, San Jose, CA (US)

(21) Appl. No.: 19/529,574

(22) Filed: Feb. 4, 2026

Related U.S. Application Data
(60) Provisional application No. 63/770,890, filed on Mar. 12, 2025.
(60) Provisional application No. 63/770,883, filed on Mar. 12, 2025.
(60) Provisional application No. 63/770,874, filed on Mar. 12, 2025.
(60) Provisional application No. 63/770,870, filed on Mar. 12, 2025.
(60) Provisional application No. 63/770,866, filed on Mar. 12, 2025.
(60) Provisional application No. 63/770,791, filed on Mar. 12, 2025.
(60) Provisional application No. 63/770,782, filed on Mar. 12, 2025.
(60) Provisional application No. 63/770,585, filed on Mar. 12, 2025.
(60) Provisional application No. 63/770,591, filed on Mar. 12, 2025.
(60) Provisional application No. 63/770,592, filed on Mar. 12, 2025.
(60) Provisional application No. 63/770,785, filed on Mar. 12, 2025.
(60) Provisional application No. 63/772,735, filed on Mar. 16, 2025.
(60) Provisional application No. 63/772,741, filed on Mar. 17, 2025.
(60) Provisional application No. 63/772,740, filed on Mar. 17, 2025.
(60) Provisional application No. 63/772,739, filed on Mar. 17, 2025.
(60) Provisional application No. 63/772,738, filed on Mar. 17, 2025.

(51) Int. Cl. H10N 19/00; H10N 10/17

(52) U.S. Cl. CPC H10N 19/00; H10N 10/17

(57) ABSTRACT

A thermoelectric cooler module comprises a first electrically conductive plate. A second electrically conductive plate is arranged substantially parallel to the first electrically conductive plate and spaced apart therefrom by a predetermined distance. A plurality of semiconductor pellet pairs are disposed between the first electrically conductive plate and the second electrically conductive plate. Each semiconductor pellet pair comprises a P-type semiconductor pellet and an N-type semiconductor pellet. A plurality of conductive traces are disposed on surfaces of the first electrically conductive plate and the second electrically conductive plate. The conductive traces electrically couple the semiconductor pellet pairs in series to form a continuous electrical path. A positive terminal is electrically coupled to the continuous electrical path. A neutral terminal is electrically coupled to the continuous electrical path. Adjacent semiconductor pellets are separated by gaps of predetermined width to provide electrical isolation and accommodate thermal expansion.

### CLAIM OF PRIORITY

This application claims priority to U.S. Provisional Patent Application No. 63/772,741, filed on Mar. 17, 2025. This provisional patent application is hereby incorporated by reference.

This application claims priority to U.S. Provisional Patent Application No. 63/772,740, filed on Mar. 17, 2025. This provisional patent application is hereby incorporated by reference.

This application claims priority to U.S. Provisional Patent Application No. 63/772,739, filed on Mar. 17, 2025. This provisional patent application is hereby incorporated by reference.

This application claims priority to U.S. Provisional Patent Application No. 63/772,738, filed on Mar. 17, 2025. This provisional patent application is hereby incorporated by reference.

This application claims priority to U.S. Provisional Patent Application No. 63/772,735, filed on Mar. 16, 2025. This provisional patent application is hereby incorporated by reference.

This application claims priority to U.S. Provisional Patent Application No. 63/770,890, filed on Mar. 12, 2025. This provisional patent application is hereby incorporated by reference.

This application claims priority to U.S. Provisional Patent Application No. 63/770,883, filed on Mar. 12, 2025. This provisional patent application is hereby incorporated by reference.

This application claims priority to U.S. Provisional Patent Application No. 63/770,874, filed on Mar. 12, 2025. This provisional patent application is hereby incorporated by reference.

This application claims priority to U.S. Provisional Patent Application No. 63/770,870, filed on Mar. 12, 2025. This provisional patent application is hereby incorporated by reference.

This application claims priority to U.S. Provisional Patent Application No. 63/770,866, filed on Mar. 12, 2025. This provisional patent application is hereby incorporated by reference.

This application claims priority to U.S. Provisional Patent Application No. 63/770,791, filed on Mar. 12, 2025. This provisional patent application is hereby incorporated by reference.

This patent application claims priority to U.S. Provisional Patent Application No. 63/770,782, filed on Mar. 12, 2025. This United States Provisional Patent Application is hereby incorporated by reference in its entirety.

This application claims priority to U.S. Provisional Patent Application No. 63/770,585, filed on Mar. 12, 2025. This United States Provisional Patent Application is hereby incorporated by reference in its entirety.

This patent application claims priority to U.S. Provisional Patent Application No. 63/770,591, filed on Mar. 12, 2025. This United States Provisional Patent Application is hereby incorporated by reference in its entirety.

This patent application claims priority to U.S. Provisional Patent Application No. 63/770,592, filed on Mar. 12, 2025. This United States Provisional Patent Application is hereby incorporated by reference in its entirety.

This application claims priority to U.S. Provisional Patent Application No. 63/770,785 filed on Mar. 12, 2025. United States Provisional Patent Application No. 63/770,785 is incorporated by reference in its entirety.

### BACKGROUND

### Field of the Invention

The present invention relates to portable temperature-controlled storage systems, and more particularly to an Fixed-Footprint Thermoelectric Systems with Variable Junction Density.

### Background

Thermoelectric coolers utilize the Peltier effect to achieve solid-state cooling through semiconductor pellet arrays disposed between conductive plates. When electric current flows through series-connected P-type and N-type semiconductor pellet pairs, heat is absorbed at one surface and rejected at the opposite surface, creating a temperature differential. Conventional thermoelectric cooler designs employ varying numbers of semiconductor pellet pairs to accommodate different thermal management requirements.

High-density thermoelectric cooler configurations employing large numbers of pellet pairs, such as 128 pairs or more, are designed for high-heat-flux applications including microprocessor cooling and power electronics thermal management. These high-density designs can handle thermal loads exceeding 100 Watts per square centimeter but require substantial electrical current, involve significant material costs, and present manufacturing complexity challenges. The dense pellet packing in such designs can result in reduced manufacturing yields and increased susceptibility to mechanical stress from thermal expansion mismatches.

Intermediate thermoelectric cooler configurations employing moderate numbers of pellet pairs, such as 50 pairs, provide cooling capacity for thermal loads in the range of 50 to 100 Watts per square centimeter. While these intermediate designs offer reduced material costs compared to high-density configurations, they remain optimized for thermal loads that exceed the requirements of many portable cooling applications, consumer electronics, and moderate-duty thermal management systems.

A gap exists in the thermoelectric cooler design spectrum for configurations specifically optimized for lower thermal load applications in the range of 5 to 30 Watts per square centimeter. Applications such as portable temperature-controlled enclosures, medical sample storage, pharmaceutical transport, compact electronic device cooling, and beverage cooling systems generate moderate heat loads that do not require the cooling capacity of high-density or intermediate thermoelectric cooler designs. Existing thermoelectric coolers applied to such moderate thermal load applications are over-designed, resulting in unnecessary material costs, excessive electrical current requirements, and manufacturing complexity that increases unit costs without corresponding performance benefits.

Additionally, conventional thermoelectric cooler designs have not optimized the relationship between pellet dimensions, gap spacing, and pellet packing fraction for moderate thermal load applications. The pellet aspect ratios, gap widths, and spatial arrangements in existing designs are generally derived from high-density optimization approaches that prioritize maximum heat pumping capacity rather than balanced performance for cost-effective moderate-duty cooling. There exists a need for a thermoelectric cooler architecture that achieves an optimal balance between cooling capacity, material cost, electrical current requirements, manufacturing feasibility, and reliability for moderate thermal load applications.

Furthermore, thermoelectric material property combinations have not been specifically tailored to work synergistically with reduced pellet count configurations. The selection of Seebeck coefficients, electrical conductivities, thermal conductivities, and figures of merit in conventional designs typically assumes pellet counts and current densities appropriate for high-density applications, without optimization for the electrical and thermal characteristics of reduced pellet count architectures.

There is accordingly a need for a thermoelectric cooler design that addresses these deficiencies by providing a reduced pellet count configuration specifically engineered for moderate thermal load applications, with optimized dimensional relationships, material properties, and scalability characteristics that achieve cost-effective cooling performance while maintaining manufacturing feasibility and long-term reliability.

### BRIEF SUMMARY OF THE INVENTION

A thermoelectric cooler module comprises a first electrically conductive plate. A second electrically conductive plate is arranged substantially parallel to the first electrically conductive plate and spaced apart therefrom by a predetermined distance. A plurality of semiconductor pellet pairs are disposed between the first electrically conductive plate and the second electrically conductive plate. Each semiconductor pellet pair comprises a P-type semiconductor pellet and an N-type semiconductor pellet. A plurality of conductive traces are disposed on surfaces of the first electrically conductive plate and the second electrically conductive plate. The conductive traces electrically couple the semiconductor pellet pairs in series to form a continuous electrical path. A positive terminal is electrically coupled to the continuous electrical path. A neutral terminal is electrically coupled to the continuous electrical path. Adjacent semiconductor pellets are separated by gaps of predetermined width to provide electrical isolation and accommodate thermal expansion.

### BRIEF DESCRIPTION OF THE DRAWINGS

FIG. 1 is a top view of example embodiment of a portable temperature-controlled enclosure, according to some embodiments.

FIGS. 2 and 3 are isometric views of example embodiment of a portable temperature-controlled enclosure, according to some embodiments.

FIG. 4 is a front view of example embodiment of a portable temperature-controlled enclosure, according to some embodiments.

FIG. 5 is a side view of example embodiment of a portable temperature-controlled enclosure, according to some embodiments.

FIG. 6-9 illustrate various example views of an aluminum cooling chamber portable unit, according to some embodiments.

FIG. 6 illustrates a top-view of aluminum cooling chamber portable unit, according to some embodiments.

FIG. 7 illustrates a isometric-view of aluminum cooling chamber portable unit, according to some embodiments.

FIG. 8 illustrates a rear-view of aluminum cooling chamber portable unit, according to some embodiments.

FIG. 9 illustrates a side-view of aluminum cooling chamber portable unit, according to some embodiments.

FIG. 10 is a block diagram of a sample computing environment that can be utilized to implement various embodiments.

FIG. 11 illustrates a logical view of a portable temperature-controlled enclosure, according to some embodiments.

FIG. 12 illustrates an isometric view of a thermoelectric cooler module in an assembled configuration, according to some embodiments.

FIG. 13 illustrates an isometric view of the semiconductor pellet array with the first and second electrically conductive plates removed to reveal the internal structure and electrical configuration of the thermoelectric cooler module, according to some embodiments.

The Figures described above are a representative set and are not an exhaustive with respect to embodying the invention.

### DESCRIPTION

Disclosed are a system, method, and article of manufacture for an Thermoelectric Cooler (TEC) densely placed semiconductor pellets. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment, according to some embodiments. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown. Appendix A includes additional information for implementing various embodiments.

### DEFINITIONS

Example definitions for some embodiments are now provided.

Acrylonitrile butadiene styrene (ABS) is a common plastic polymer.

High-density polyethylene (HDPE) or polyethylene high-density (PEHD) is a polyethylene thermoplastic made from petroleum.

The thermo-electric effect is the presence of heating or cooling at an electrified junction of two different conductors. When a current is made to flow through a junction between two conductors, A and B, heat may be generated or removed at the junction. Thermo-electric cooling uses the Peltier effect to create a heat flux between the junction of two different types of materials. A thermoelectric cooler, heater, or thermoelectric heat pump is a solid-state active heat pump which transfers heat from one side of the device to the other, with consumption of electrical energy, depending on the direction of the current.

Thermal control material (TCM) is a substance with a high heat of fusion which, melting and solidifying at a certain temperature, is capable of storing and releasing large amounts of energy. Heat is absorbed or released when the material changes from solid to liquid and vice versa. Example TCM materials can include, inter alia: organic (paraffin and nonparaffin), inorganic (salt hydrates and metallic alloys), and eutectic (mixture of two or more TCM components: organic, inorganic, and both).

Polypropylene (PP) is a thermoplastic polymer used in a wide variety of applications. It is produced via chain-growth polymerization from the monomer propylene.

Press fit or friction fit is a fastening between two parts which is achieved by friction after the parts are pushed together, rather than by any other means of fastening.

Temperature sensors can include mechanical temperature sensors, electrical temperature sensors, integrated circuit sensors, medometers, etc.

Thermoelectric effect is the direct conversion of temperature differences to electric voltage and vice versa via a thermocouple. A thermoelectric device creates voltage when there is a different temperature on each side. Conversely, when a voltage is applied to it, heat is transferred from one side to the other, creating a temperature difference. At the atomic scale, an applied temperature gradient causes charge carriers in the material to diffuse from the hot side to the cold side.

6061-T6 aluminum is a precipitation-hardened aluminum alloy containing magnesium and silicon, heat-treated to the T6 temper to provide increased strength, machinability, and corrosion resistance.

3003-H14 aluminum is a work-hardened aluminum alloy containing manganese, cold-worked to the H14 temper to increase strength while retaining high thermal conductivity and corrosion resistance.

Controlled dip-coating can be a deposition process in which a part is immersed in a liquid coating bath and withdrawn at a controlled rate such that a uniform wet film forms on the surface.

Spray-deposition can be a surface-coating process that atomizes a liquid precursor and directs droplets toward a target surface to form a continuous coating layer.

A nanostructured adhesion primer layer can be a thin film comprising nanoscale features configured to promote mechanical or chemical bonding between a substrate and an overlying coating.

A hydrocarbon material layer having a thermal diffusivity can be a coating comprising organic molecules configured to exhibit a rate of internal heat transport characterized by its thermal diffusivity.

Thermal diffusivity can be a material property defined as the ratio of thermal conductivity to volumetric heat capacity (α=k/(ρ·Cp)), indicating the rate at which heat spreads through a substance.

Hydrocarbon coating mass can be a quantity of applied hydrocarbon coating material measured as the total mass present on a coated surface.

### Example Smart Refrigerator Exterior Views

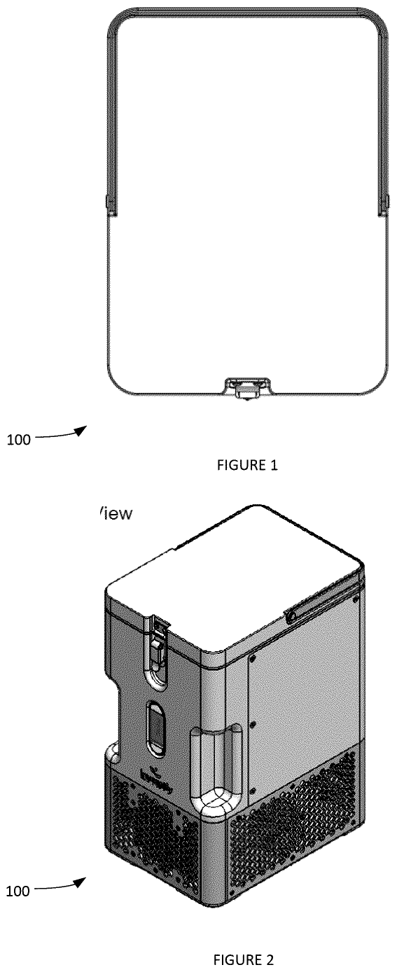

FIGS. 1-5 provide series of views of an example embodiment of a portable temperature-controlled enclosure 100, according to some embodiments. The series of views includes a set of orthographic views (e.g. top, front, side, and isometric) of the portable temperature-controlled enclosure according to one embodiment. The example embodiment of a portable temperature-controlled enclosure 100 can be a top loaded system. Portable temperature-controlled enclosure 100 can include an optimized solid-state cooling system (e.g. see infra). Portable temperature-controlled enclosure 100 provides a portable temperature-controlled enclosure utilizing an innovative solid-state cooling system with optimized thermal management. Portable temperature-controlled enclosure 100 combines advanced thermoelectric cooling technology with sophisticated control systems to achieve superior temperature stability and extended battery operation.

Portable temperature-controlled enclosure 100 comprises several key components working in concert: a precision-engineered payload chamber for storing temperature-sensitive materials, an optimized thermoelectric cooling system with angular mounting configuration, an integrated thermal control material(TCM) chamber for thermal buffering, and a sophisticated heat dissipation system including honeycomb ventilation. These components are managed by advanced monitoring and control systems, all supported by extended battery-powered operation capability.

The top-loading portable temperature-controlled enclosure 100 represents a breakthrough in portable refrigeration technology, utilizing solid-state cooling principles to maintain precise temperature control. The top-loading portable temperature-controlled enclosure 100 distinguishes itself through the complete elimination of traditional cooling infrastructure components such as compressors, refrigerant gases, cooling coils, ice packs, or gel packs.

Example physical specifications of the top-loading portable temperature-controlled enclosure 100 are now discussed. The top-loading portable temperature-controlled enclosure 100 payload capacity, by way of example, can be a one (1) liter. The top-loading portable temperature-controlled enclosure 100 can include a top-loading design with example dimensions of 107.78 mm×119.92 mm×166.84 mm.

Access to the top-loading portable temperature-controlled enclosure 100 can be via a top-mounted lid providing full access to internal chamber. Construction of The top-loading portable temperature-controlled enclosure 100 can include precision-engineered aluminum chamber with integrated cooling system.

An example Core Cooling Technology of the top-loading portable temperature-controlled enclosure 100 is now discussed. The top-loading portable temperature-controlled enclosure 100 employs an advanced solid-state cooling mechanism based on semiconductor physics. As a cooling principle, the top-loading portable temperature-controlled enclosure 100 utilizes an electron mobility differential between semiconductor materials. By way of operation, the top-loading portable temperature-controlled enclosure 100 uses an electric current passage through dual-semiconductor junction.

The thermal control during electron transition between materials is implemented to optimize cooling efficiency. The top-loading portable temperature-controlled enclosure 100 can achieve target temperature (2° C.) within 2-hour initialization period. The top-loading portable temperature-controlled enclosure 100 implements temperature maintenance to maintain 2-8° C. range for 72 hours without external power.

An example Thermal Management System of the internal payload chamber incorporates a sophisticated thermal management design. As seen below, the top-loading portable temperature-controlled enclosure 100 includes a chamber construction that includes payload 104. Here, the material composition can include a specialized heat-absorbing material combined with aluminum. The top-loading portable temperature-controlled enclosure 100 utilizes thermal spreading via an engineered aluminum structure for optimal temperature distribution. The top-loading portable temperature-controlled enclosure 100 performs heat absorption via a material matrix for thermal energy management.

The top-loading portable temperature-controlled enclosure 100 provides dynamic temperature control. Primary cooling is performed via a solid-state semiconductor chip (e.g. discussed infra). Supplementary cooling can be performed via a thermal mass buffer system. Hybrid operation between thermal mass and active cooling Response system can be used for temperature maintenance. Automated cooling bursts for temperature deviation compensation can be performed.

The top-loading portable temperature-controlled enclosure 100 can include a power and environmental adaptation power system 1102. The top-loading portable temperature-controlled enclosure 100 includes an input compatibility, by way of example of a Universal AC power (110V/220V) and an integrated charging system. Battery operation can be for 72-hour autonomous operation capability.

Optimized power consumption during steady-state operation can be obtained using bi-directional temperature control capability. For example, in a winter mode operation, the top-loading portable temperature-controlled enclosure 100 functions in extreme cold environments (−20° C. to −30° C.). Thermal management systems 1104 of the top-loading portable temperature-controlled enclosure 100 can maintains 2-8° C. in both hot and cold ambient conditions. An example environmental range enables The top-loading portable temperature-controlled enclosure 100 to be functional across extreme temperature variations.

The top-loading portable temperature-controlled enclosure 100 includes a monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording. The top-loading portable temperature-controlled enclosure 100 can also perform automated cloud data synchronization.

The top-loading portable temperature-controlled enclosure 100 includes an Operation and Performance Temperature Performance module that manages an initial cooldown (e.g. 2 hours to reach target temperature with a temperature range: 2-8° C. maintenance and operation duration of 72 hours on battery power).

A thermal interface material utilizes a high thermal conductivity compound with controlled thickness application and full surface coverage verification. Mounting pressure can be maintained at 30-40 PSI through a spring-loaded mechanism, ensuring even pressure distribution across the chip surface and compensation for thermal expansion and contraction in some example embodiments.

The top-loading configuration represents a significant advancement in portable temperature-controlled storage, combining innovative solid-state cooling technology with sophisticated thermal management and monitoring systems. The design achieves exceptional efficiency and reliability while maintaining precise temperature control across varied environmental conditions.

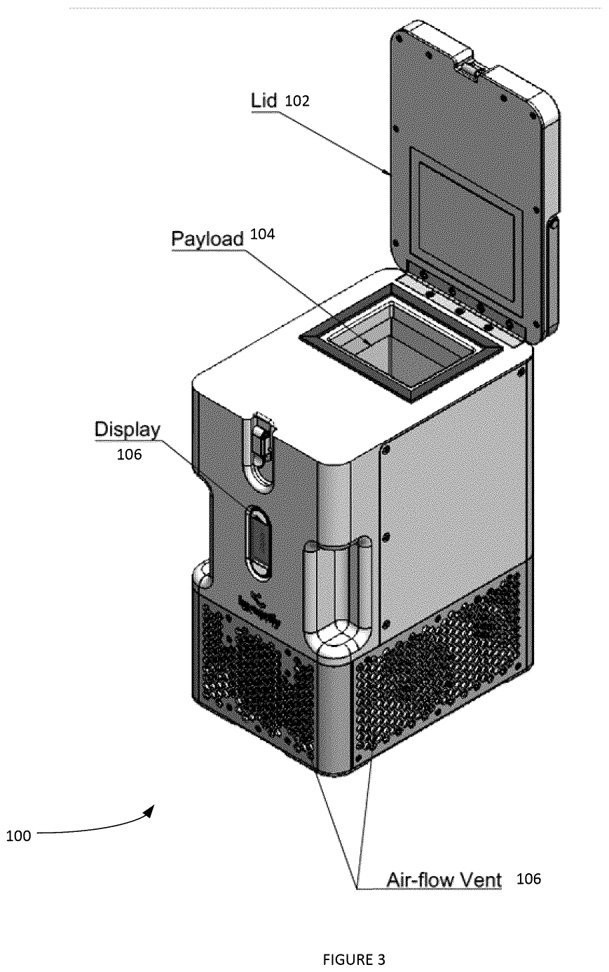

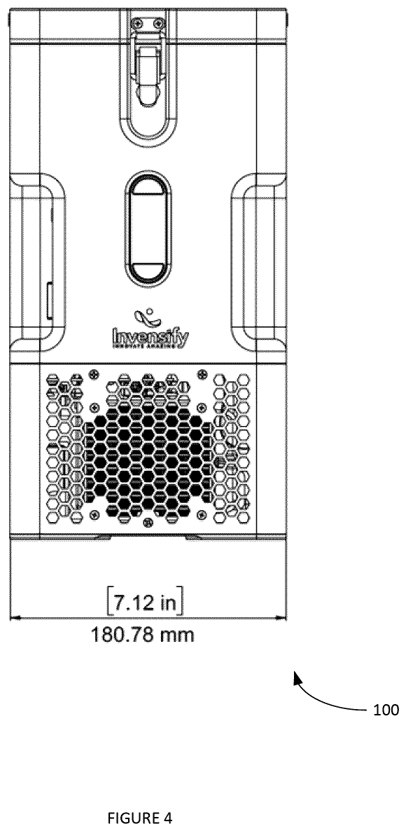

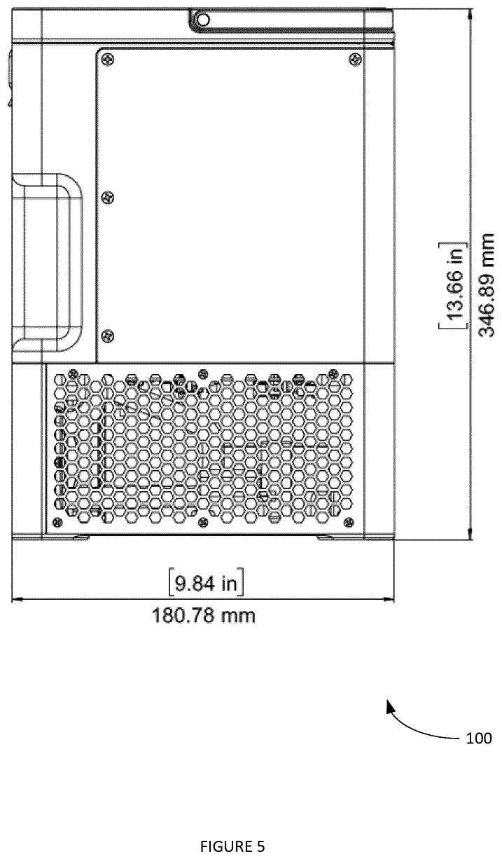

More specifically, FIG. 1 is a top view of example embodiment of a portable temperature-controlled enclosure 100, according to some embodiments. FIGS. 2 and 3 are isometric views of example embodiment of a portable temperature-controlled enclosure 100, according to some embodiments. FIG. 4 is a front view of example embodiment of a portable temperature-controlled enclosure 100, according to some embodiments. FIG. 5 is a side view of example embodiment of a portable temperature-controlled enclosure 100, according to some embodiments.

In one embodiments, portable temperature-controlled enclosure 100 can have a top-loading configuration with example payload dimensions: 3.2″×4.1″×5.5″. An example top opening capacity can be one (1) liter. Overall dimensions, by way of example, can be 107.78 mm×119.92 mm×166.84 mm. Portable temperature-controlled enclosure 100 provides a top access lid for payload (e.g. medications, etc.) insertion.

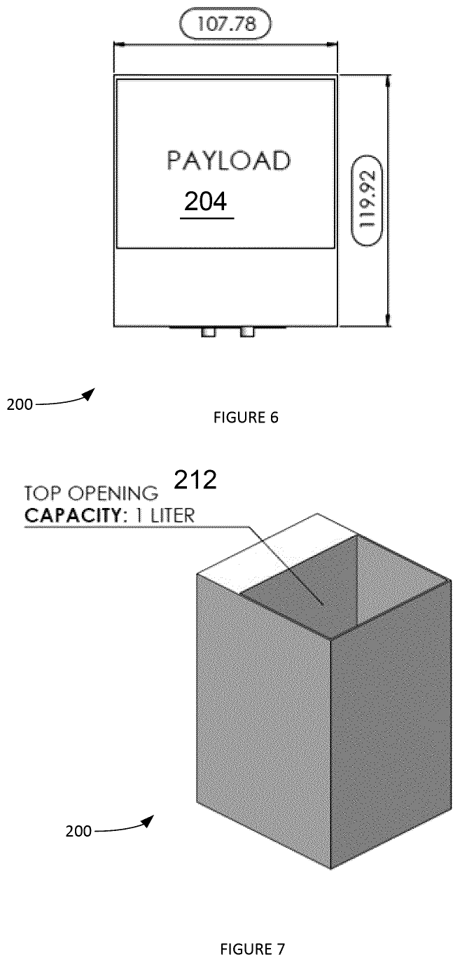

FIG. 6-9 illustrate various example views of an aluminum cooling chamber portable unit 200, according to some embodiments. Aluminum cooling chamber portable unit 200 can be the internal cooling/heating system of portable temperature-controlled enclosure 100.

Aluminum cooling chamber portable unit 200 of portable temperature-controlled enclosure 100 comprises a sophisticated thermoelectric cooling mechanism wherein electrical power is transmitted through a strategically positioned semiconductor chip 202 mounted at a calculated angular orientation relative to the aluminum payload chamber 204. The semiconductor chip 202 incorporates a material combination wherein electrons traverse between different semiconductor elements, creating an thermal control effect at the material junction interfaces. This thermal control phenomenon, occurring at the precise locations where the material composition transitions, facilitates the cooling process through electron mobility differentials between the semiconductor materials.

The thermal management system utilizes direct thermal coupling between the semiconductor chip 202 and an aluminum payload chamber 204, whereby the thermal control at the material junctions actively extracts heat from the payload area through the aluminum wall interface. The extracted thermal energy is subsequently transferred to a closed-loop cooling system 206 comprising fluid-carrying pipes 208 directly coupled to the posterior surface of the semiconductor chip (e.g. can include a heat sink system). The cooling loop 206 employs either water or antifreeze as the working fluid, circulating through an engineered pipe network via an integrated pump mechanism.

The system's thermal circuit can be completed through a fan-assisted heat exchanger configuration 214, wherein the heated working fluid from the cooling loop 206 is actively cooled before being recirculated through the system. The angular mounting of the semiconductor chip, deliberately oriented at a calculated angle rather than perpendicular to the payload chamber, achieves enhanced cooling distribution by optimizing the radius of coolness spread and increasing the effective surface area coverage. This angular configuration demonstrably improves the speed and uniformity of temperature distribution compared to traditional perpendicular mounting arrangements.

The thermal control system can operate in a dual-power configuration, initially utilizing wall power for the cooldown phase until the target temperature (typically 2° C.) is achieved, at which point the system transitions to battery power through a lithium polymer battery assembly capable of maintaining temperature control for 72 hours of autonomous operation. The internal configuration includes various top-loading variants (e.g. via top opening 212, etc.) while maintaining identical operational principles, with the semiconductor chip positioning optimized for each configuration to maximize cooling efficiency through enhanced radial distribution patterns.

The angular orientation of the semiconductor chip 202 relative to the payload chamber wall facilitates superior thermal spreading characteristics. The cooling effect disperses in a radial pattern rather than traditional linear distribution, resulting in more efficient coverage of the payload surface area and accelerated temperature equalization throughout the chamber. This geometric optimization of the semiconductor chip 202 placement enables the system to achieve more comprehensive thermal coverage compared to conventional perpendicular mounting configurations, as the angular positioning creates an expanded radius of cooling influence that enhances the overall heat absorption efficiency of the system.

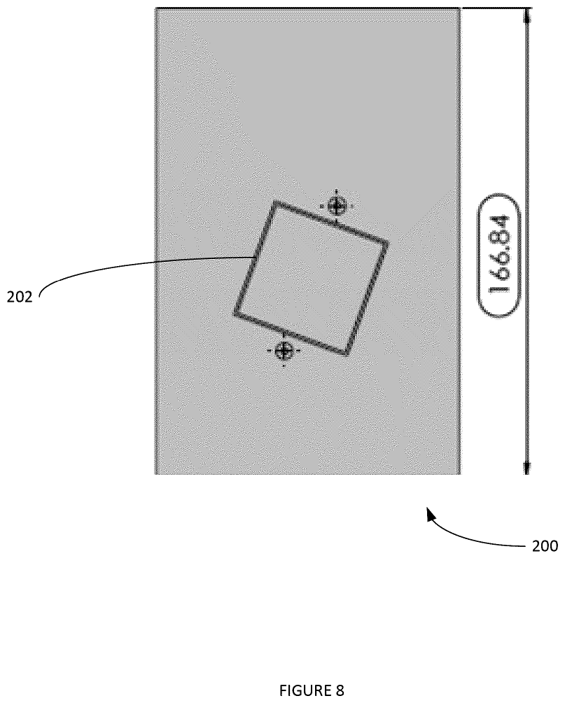

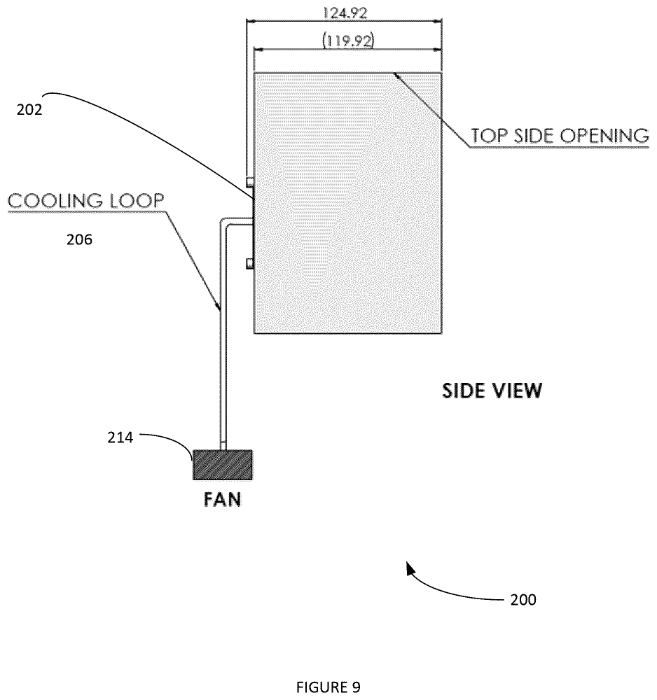

More specifically, FIG. 6 illustrates a top-view of aluminum cooling chamber portable unit 200, according to some embodiments. FIG. 7 illustrates a isometric-view of aluminum cooling chamber portable unit 200, according to some embodiments. FIG. 8 illustrates a rear-view of aluminum cooling chamber portable unit 200, according to some embodiments. FIG. 9 illustrates a side-view of aluminum cooling chamber portable unit 200, according to some embodiments.

### Example Computer Architecture and Systems

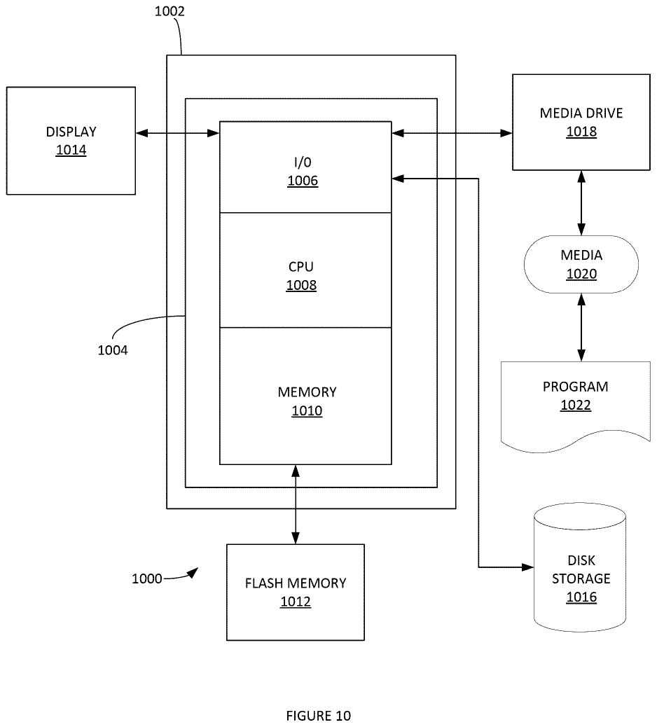

FIG. 10 depicts an exemplary computing system 1000 that can be configured to perform any one of the processes provided herein. In this context, computing system 1000 may include, for example, a processor, memory, storage, and I/O devices (e.g., monitor, keyboard, disk drive, Internet connection, etc.). However, computing system 1000 may include circuitry or other specialized hardware for carrying out some or all aspects of the processes. In some operational settings, computing system 1000 may be configured as a system that includes one or more units, each of which is configured to carry out some aspects of the processes either in software, hardware, or some combination thereof.

FIG. 10 depicts computing system 1000 with a number of components that may be used to perform any of the processes described herein. The main system 1002 includes a motherboard 1004 having an I/O section 1006, one or more central processing units (CPU) 1008, and a memory section 1010, which may have a flash memory card 1012 related to it. The I/O section 1006 can be connected to a display 1014, a keyboard and/or other user input (not shown), a disk storage unit 1016, and a media drive unit 1018. The media drive unit 1018 can read/write a computer-readable medium 1020, which can contain programs 1022 and/or data. Computing system 1000 can include a web browser. Moreover, it is noted that computing system 1000 can be configured to include additional systems in order to fulfill various functionalities. Computing system 1000 can communicate with other computing devices based on various computer communication protocols such a Wi-Fi, Bluetooth® (and/or other standards for ex-changing data over short distances includes those using short-wavelength radio transmissions), USB, Ethernet, cellular, an ultrasonic local area communication protocol, etc.

Thermo-electric cooler pump can be managed by a computing system in the portable smart refrigerator. The computing system can be coupled with an exterior display. Exterior display can display various parameters (e.g. temperature, battery power, etc.) of the portable smart refrigerator. Computing system can also be coupled with various other systems such as, inter alia: temperature sensors, digital clocks, Wi-Fi systems, etc.

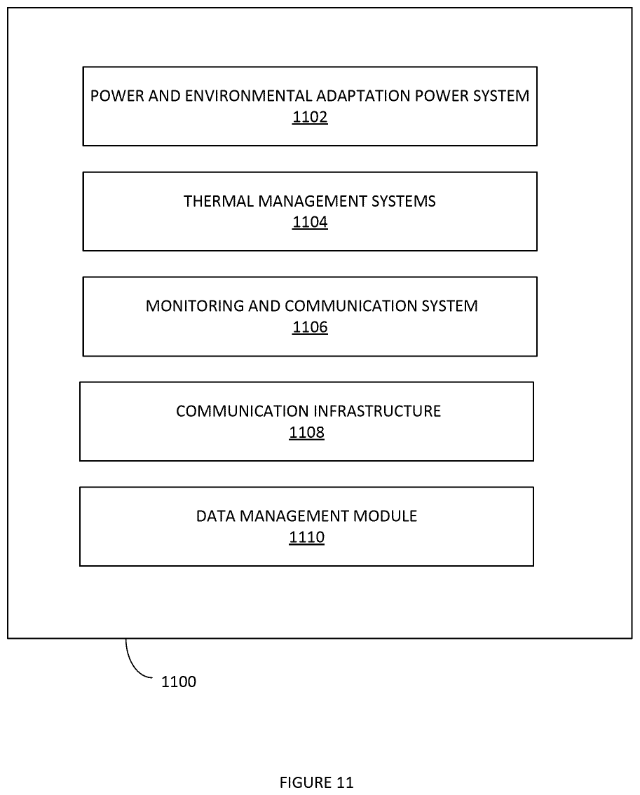

FIG. 11 illustrates a logical view 1100 of a portable temperature-controlled enclosure, according to some embodiments. Power and environmental adaptation power system 1102. The top-loading portable temperature-controlled enclosure 100 includes an input compatibility, by way of example of a Universal AC power (110V/220V) and an integrated charging system. Thermal management systems 1104 manage the temperature of top-loading portable temperature-controlled enclosure 100. Thermal management systems 110 of the top-loading portable temperature-controlled enclosure 100 can maintain 2-8° C. in both hot and cold ambient conditions. Monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording.

Additional information on chip positioning is now discussed. The innovative cooling system centers around a precisely engineered 40 mm×40 mm semiconductor chip that represents a significant advancement in portable refrigeration technology. This chip, comprising multiple semiconductor junctions arranged in an optimized pattern, is mounted at a carefully calculated 20-degree angle relative to the payload chamber wall, deviating from traditional perpendicular mounting approaches. This specific angular orientation was chosen to maximize the cooling efficiency through enhanced radial distribution patterns.

The mounting configuration creates a sophisticated thermal management system where the chip interfaces directly with the aluminum chamber wall for maximum thermal conductivity. This direct coupling is maintained by a spring-loaded mechanism that ensures a consistent 30-40 PSI mounting pressure, crucial for optimal heat transfer. The interface between the chip and wall utilizes a high thermal conductivity compound with carefully controlled thickness and verified full surface coverage.

The 20-degree mounting angle serves a critical purpose in the system's operation. Unlike conventional perpendicular mounting, which typically results in linear cooling distribution, this angular orientation creates an expanded radius of cooling influence. This radial distribution pattern enables more comprehensive coverage of the payload surface area and facilitates faster temperature equalization throughout the chamber. The result is a more efficient and effective cooling system that achieves superior thermal coverage compared to traditional mounting configurations.

In the top-loaded configuration, the chip is positioned lower, near the midsection of the wall, with the temperature sensor strategically placed inside the payload wall towards the bottom side. This positioning was specifically chosen to optimize the cooling effect in relation to the temperature sensor location. The entire setup demonstrates a carefully engineered approach to thermal management, where each component's position has been optimized for maximum efficiency.

The semiconductor chip's design and mounting create a cooling effect that disperses in a radial pattern rather than a traditional linear distribution. This radial dispersion is particularly effective because it provides more uniform coverage across the payload area. The angular mounting effectively increases the total area over which the cooling effect spreads, resulting in more efficient temperature control throughout the chamber. This innovative approach to chip mounting and cooling distribution represents a significant advancement in portable refrigeration technology, offering improved performance over conventional perpendicular mounting systems.

The system's overall design reflects a deep understanding of thermal dynamics and practical engineering considerations. By combining the precise 40 mm×40 mm chip dimensions with the 20-degree mounting angle and strategic positioning relative to temperature sensors, the system achieves optimal cooling performance while maintaining efficient use of space within the portable unit. The careful attention to mounting pressure, thermal compound application, and interface design ensures reliable and consistent performance, making this cooling system particularly well-suited for portable applications requiring precise temperature control.

Various embodiments of a thermoelectric cooler (TEC) design incorporating standard semiconductor pellets are disclosed herein. The present disclosure describes a TEC architecture optimized for moderate thermal load applications, featuring a reduced pellet count configuration that provides cost-effective cooling performance. The thermoelectric cooler operates on solid-state principles, eliminating the need for mechanical compressors, refrigerants, or moving parts common in conventional cooling systems.

In one embodiment, a thermoelectric cooler module comprises a first electrically conductive plate and a second electrically conductive plate arranged parallel to each other and spaced apart by a predetermined distance. The plates can be fabricated from high thermal conductivity materials including but not limited to copper, aluminum, or ceramic substrates with metallized surfaces. A plurality of semiconductor pellet pairs are disposed between the first and second plates, wherein each pellet pair comprises a P-type semiconductor pellet and an N-type semiconductor pellet. Conductive traces electrically couple the pellet pairs in series, forming a continuous electrical path from a positive terminal to a neutral terminal. The conductive traces can comprise copper, silver, gold, or other highly conductive metals, and can be applied through electroplating, sputtering, screen printing, or other metallization techniques.

According to certain embodiments, the thermoelectric cooler comprises exactly eighteen (18) pairs of semiconductor pellets arranged in a predetermined pattern between the first and second plates. This pellet count represents a significant reduction compared to higher-density configurations, while maintaining sufficient thermoelectric performance for applications with moderate heat generation requirements. The arrangement of pellets can follow a rectangular grid pattern, a hexagonal close-packed arrangement, or other geometric configurations optimized for uniform current distribution and thermal performance. The eighteen-pair configuration provides a pellet density that balances electrical resistance, thermal impedance, and manufacturing feasibility.

In one implementation, each semiconductor pellet has a square cross-sectional area and a predetermined height, establishing a defined aspect ratio that influences both electrical and thermal performance characteristics. The aspect ratio of pellet height to cross-sectional dimension affects the electrical resistance and thermal conductance of each pellet element. Adjacent pellets are separated by gaps of predetermined width, allowing for thermal expansion and providing electrical isolation between pellets of the same polarity. The gaps can be filled with electrically insulating materials such as silicone, epoxy, ceramic-filled polymers, or air gaps maintained by structural supports. The first and second plates each have a uniform thickness sufficient to provide mechanical rigidity while minimizing thermal resistance, and the conductive traces disposed on surfaces of the plates have a trace thickness less than the plate thickness to reduce parasitic heat conduction while maintaining adequate electrical conductivity.

When electric current is applied through the series-connected pellet pairs from the positive terminal toward the neutral terminal, a thermoelectric effect occurs at junctions where the semiconductor pellets interface with the conductive traces. Energy absorption manifests at one plate surface while heat rejection occurs at the opposite plate surface, thereby creating a temperature differential across the module. The magnitude of heat transfer is proportional to the current flowing through the device and the Seebeck coefficient of the thermoelectric materials. The maximum temperature differential achievable depends on the thermoelectric figure of merit of the materials, the thermal conductance of the module, and parasitic heat losses.

According to certain embodiments, the P-type semiconductor material exhibits a Seebeck coefficient of approximately 210 μV/K, an electrical conductivity of approximately 1.4×10⁵ S/m (Siemens per meter), a thermal conductivity of approximately 1.2 W/(m·K) (Watts per meter-Kelvin), and a thermoelectric figure of merit (α²σ/κ) of approximately 5.2×10⁻³ K⁻¹ (per Kelvin). The N-type semiconductor material exhibits a Seebeck coefficient of approximately −170 μV/K, an electrical conductivity of approximately 1.655×10⁵ S/m, a thermal conductivity of approximately 1.2 W/(m·K), and a thermoelectric figure of merit of approximately 4.0×10⁻³ K⁻¹. The Seebeck coefficient describes the magnitude of voltage generated per unit temperature difference, with opposite signs for P-type and N-type materials ensuring additive voltage generation across each thermocouple pair. The electrical conductivity determines the ohmic losses and electrical resistance of the pellets. The thermal conductivity affects the parasitic heat backflow from hot to cold side, with lower values being preferable. The figure of merit is a dimensionless parameter that characterizes the overall efficiency of the thermoelectric material, with higher values indicating better performance.

The material properties disclosed herein represent measurements at or near room temperature (approximately 25° C. or 298 K), and these properties can vary with temperature according to the intrinsic temperature dependencies of the semiconductor materials. The P-type and N-type materials can be doped to achieve the specified electrical properties, with doping concentrations in the range of 10¹⁹ to 10²⁰ carriers per cubic centimeter. The materials can be fabricated through zone melting, powder metallurgy, or crystal growth techniques followed by appropriate doping processes.

The disclosed design occupies a position within a spectrum of thermoelectric cooling solutions, each optimized for specific thermal load requirements. In contrast to high-density configurations employing 128 pellet pairs suitable for high-heat-flux applications such as microprocessor cooling where heat generation can exceed 100 Watts per square centimeter, or intermediate configurations employing 50 pellet pairs for moderate-to-high thermal loads in the range of 50 to 100 Watts per square centimeter, the present 18-pellet-pair design is specifically optimized for applications generating lower thermal loads in the range of 5 to 30 Watts per square centimeter. This deliberate reduction in pellet count provides a cost-effective solution while maintaining adequate cooling capacity for the target application range. The reduced pellet count also results in lower electrical current requirements for a given temperature differential, potentially enabling operation from lower-power electrical sources including batteries or solar panels.

The relationship between pellet count and cooling capacity enables application-specific optimization based on fundamental thermoelectric principles. Higher pellet counts provide greater heat pumping capacity but at increased material cost and manufacturing complexity. The heat pumping capacity (Qc) of a thermoelectric cooler can be expressed as Qc=α·I·Tc−0.5·I²·R−K·ΔT, where α is the Seebeck coefficient, I is the current, Tc is the cold side temperature, R is the electrical resistance, K is the thermal conductance, and ΔT is the temperature difference across the module. The 18-pellet-pair configuration achieves an optimal balance between performance and economy for moderate cooling requirements, including portable temperature-controlled enclosures, compact electronic device cooling, medical sample storage, beverage cooling, and similar applications where heat generation rates are moderate and cost-effectiveness is important.

In certain embodiments, the semiconductor materials comprise bismuth telluride (Bi₂Te₃) or bismuth telluride alloys, which exhibit optimal thermoelectric performance in the temperature range from approximately −100° C. to approximately 200° C. Specific alloys can include bismuth antimony telluride ((Bi,Sb)₂Te₃) for P-type materials and bismuth telluride selenide (Bi₂(Te,Se)₃) for N-type materials. This material selection makes the disclosed design particularly suitable for applications operating near ambient temperature or requiring moderate sub-ambient cooling. Alternative thermoelectric materials such as lead telluride (PbTe) for mid-temperature applications (200° C. to 600° C.) or silicon-germanium alloys (SiGe) for high-temperature applications (600° C. to 1000° C.) can be substituted in embodiments designed for different operating temperature ranges.

The disclosed thermoelectric cooler design provides several technical advantages over conventional cooling approaches. The reduced pellet count compared to high-density alternatives results in lower material costs and simplified manufacturing processes while maintaining sufficient cooling performance for moderate thermal load applications. The standardized pellet dimensions facilitate reliable manufacturing and quality control through automated pick-and-place assembly equipment. The predetermined gap spacing between pellets accommodates thermal expansion during operation, enhancing reliability and operational lifetime by reducing mechanical stress. The solid-state operation eliminates wear mechanisms associated with mechanical cooling systems, providing superior reliability and maintenance-free operation. The absence of refrigerants eliminates environmental concerns and regulatory compliance requirements associated with traditional vapor-compression cooling systems.

The thermoelectric cooler module can be operated in steady-state mode where constant current is applied to maintain a fixed temperature differential, or in pulsed mode where current is modulated to achieve rapid thermal transients or to optimize power consumption. The module exhibits bidirectional operation capability, functioning as a cooler when current flows in one direction and as a heater when current is reversed, providing versatile temperature control functionality. The response time of the thermoelectric cooler can be on the order of seconds to minutes depending on the thermal mass of the system being cooled.

Thermal interface materials can be applied to the outer surfaces of the first and second plates to minimize thermal contact resistance when the thermoelectric cooler is integrated into a larger thermal management system. Such thermal interface materials can include thermal greases, phase-change materials, thermal pads, or graphite sheets that have thermal conductivities ranging from approximately 1 W/(m·K) to over 200 W/(m·K) depending on the material selected. Proper application of thermal interface materials with appropriate thickness control (in the range of 25 to 100 micrometers) is important for achieving optimal thermal performance.

Heat sinks or heat exchangers are coupled to the hot side of the thermoelectric cooler to dissipate the rejected heat, which comprises both the heat extracted from the cold side plus the electrical power input. The hot side heat dissipation can be accomplished through natural convection, forced air cooling with fans, liquid cooling with pumps and radiators, or combination approaches. The effectiveness of hot side heat rejection directly impacts the achievable temperature differential and cooling capacity, with inadequate heat dissipation resulting in elevated hot side temperatures that reduce net cooling performance through increased backflow of heat from hot to cold side.

The electrical power consumption of the thermoelectric cooler varies with the desired temperature differential and cooling load. For the 18-pellet-pair configuration disclosed herein, operating currents can range from approximately 0.5 Amperes to approximately 3 Amperes, with operating voltages ranging from approximately 1 Volt to approximately 4 Volts depending on the number of pellet pairs in series and the electrical resistance of the materials. The coefficient of performance (COP), defined as the ratio of heat pumping capacity to electrical power input, can range from approximately 0.3 to approximately 1.5 for practical operating conditions, with higher COP values achieved at smaller temperature differentials.

In one specific embodiment, the thermoelectric cooler module has overall planar dimensions of approximately 20 mm×20 mm, providing a total active cooling area of approximately 400 square millimeters. Each semiconductor pellet has a cross-sectional area of approximately 2 mm×2 mm, yielding an individual pellet area of approximately 4 square millimeters, and a height of approximately 2 mm, establishing an aspect ratio (height to width) of approximately 1:1. The gap spacing between adjacent pellets is approximately 1.4 mm, providing sufficient clearance for manufacturing tolerances, thermal expansion (on the order of 10 to 20 micrometers per degree Celsius temperature change), and electrical isolation. The first and second plates each have a thickness of approximately 0.2 mm, providing adequate mechanical strength while minimizing thermal resistance, and the conductive traces have a thickness of approximately 0.05 mm, providing sufficient electrical conductivity (with trace resistance less than 0.01 Ohms per centimeter of trace length) while minimizing parasitic heat conduction through the traces.

The 18 pellet pairs occupy a total volume of (2 mm×2 mm×2 mm)×36 pellets=288 cubic millimeters within the overall module volume of (20 mm×20 mm×2.4 mm)=960 cubic millimeters, resulting in a pellet packing fraction of approximately 30%, with the remaining volume occupied by gaps, plates, and traces. This open structure compared to high-density designs (which can achieve packing fractions exceeding 60%) provides several manufacturing and performance advantages including easier automated assembly, better tolerance for dimensional variations, and reduced mechanical stress from thermal expansion mismatches.

The pellet arrangement can follow a 3×6 rectangular grid pattern, a 2×9 pattern, a 4×4.5 staggered pattern, or other configurations that accommodate 18 pellet pairs while maintaining electrical series connectivity and optimizing for uniform current distribution and thermal performance. In one embodiment, the pellets are arranged in a 3×6 configuration with 3 rows and 6 columns, providing uniform distribution across the 20 mm×20 mm module area. The conductive traces can be routed in serpentine patterns, zigzag patterns, or other geometries that connect adjacent pellets of opposite polarity while minimizing trace length and electrical resistance.

The foregoing dimensional specifications represent one exemplary implementation, and the disclosed design principles can be scaled proportionally to accommodate different module sizes while maintaining the fundamental architecture of 18 pellet pairs with appropriate spacing and plate/trace thickness ratios. For example, a module with overall dimensions of 40 mm×40 mm would employ pellets with cross-sectional areas of approximately 4 mm×4 mm and heights of approximately 4 mm, with gap spacings of approximately 2.8 mm, plate thicknesses of approximately 0.4 mm, and trace thicknesses of approximately 0.1 mm, thereby maintaining the same dimensional ratios and pellet count while providing four times the active cooling area. Alternative embodiments can employ different overall module dimensions, pellet dimensions, gap spacings, and plate/trace thicknesses while preserving the core inventive concept of a reduced-pellet-count thermoelectric cooler optimized for moderate thermal load applications. For instance, rectangular modules with dimensions such as 15 mm×30 mm, 25 mm×25 mm, or 30 mm×15 mm can be constructed using the same 18-pellet-pair architecture with pellet arrangements optimized for the specific module geometry. Non-square pellet cross-sections such as rectangular pellets (for example, 1.5 mm×3 mm) or circular pellets (for example, 2 mm diameter) can be employed in alternative embodiments while maintaining the fundamental operating principles and performance characteristics disclosed herein.

The dimensional specifications disclosed herein are compatible with standard semiconductor manufacturing techniques including dicing, wire bonding, flip-chip bonding, and surface-mount assembly processes, facilitating integration with existing manufacturing infrastructure. The 2 mm pellet dimensions are large enough to be handled by conventional pick-and-place equipment while small enough to achieve uniform current distribution and to minimize thermal stress from temperature gradients across individual pellets. The 1.4 mm gap spacing is sufficient to prevent electrical breakdown at operating voltages (e.g., less than 5 Volts) even in the presence of moisture or contamination, while not being so large as to waste valuable module area or require excessively long conductive traces.

The thermoelectric cooler module can be manufactured using various assembly techniques suitable for microelectronic device fabrication. In one approach, the semiconductor pellets are fabricated separately through processes including ingot growth, dicing into individual pellets, and surface preparation, then assembled onto pre-fabricated substrate plates using automated pick-and-place equipment. Conductive bonding can be achieved through soldering using tin-silver-copper or bismuth-tin solders, conductive epoxy bonding using silver-filled or copper-filled adhesives, or thermocompression bonding using gold or copper intermediate layers. In an alternative approach, the pellets can be formed in situ through thick-film deposition techniques, screen printing of thermoelectric pastes, or selective area deposition followed by sintering or annealing to achieve the desired material properties. Such integrated fabrication approaches can provide cost advantages for high-volume manufacturing while potentially compromising the achievable material properties compared to bulk-grown semiconductor materials.

Quality control testing of the manufactured modules can include electrical resistance measurements to verify proper pellet-to-trace connections, thermal performance testing under standardized conditions to measure heat pumping capacity and coefficient of performance, and reliability testing including thermal cycling, humidity exposure, and mechanical shock to ensure long-term operational stability. Acceptable modules exhibit electrical resistance values within ±10% of design specifications, heat pumping capacities within ±15% of nominal values, and no performance degradation after 1000 thermal cycles between the specified operating temperature range.

The disclosed thermoelectric cooler design with 18 pellet pairs provides a technically optimized and economically viable solution for moderate thermal load applications, combining the advantages of solid-state cooling technology with practical manufacturing considerations and application-specific performance characteristics. The thermoelectric cooler module can be integrated into portable temperature-controlled enclosures for medical sample storage, pharmaceutical transport, beverage cooling, or other applications requiring precise temperature control in compact form factors. The module can be coupled with battery power sources to enable autonomous operation, with lithium polymer batteries or other rechargeable battery technologies providing electrical power for periods ranging from several hours to multiple days depending on the thermal load and ambient conditions. The module can further be integrated with control systems comprising temperature sensors, microcontrollers, and power management circuits to maintain desired temperature setpoints through feedback control of the applied electrical current.

According to certain embodiments, the thermoelectric cooler comprises exactly eighteen (18) pairs of semiconductor pellets arranged in a predetermined pattern between the first and second plates. The selection of eighteen pairs represents an optimization point within the thermoelectric cooling design spectrum distinct from high-density configurations employing 128 pellet pairs and intermediate configurations employing 50 pellet pairs. The eighteen-pair configuration provides a reduced-pellet-count architecture engineered for moderate thermal load applications generating heat in the range of 5 to 30 Watts per square centimeter. The eighteen-pair configuration achieves a balance between cooling capacity, material cost, electrical current requirements, and structural complexity for applications including portable temperature-controlled enclosures, medical sample storage devices, and compact electronic device cooling systems.

In certain embodiments, each semiconductor pellet has a cross-sectional area of approximately 2 mm×2 mm and a height of approximately 2 mm, establishing an aspect ratio of approximately 1:1. The gap spacing between adjacent pellets is approximately 1.4 mm. This combination creates a pellet packing fraction of approximately 30% within the module volume, wherein the remaining volume is occupied by gaps, plates, and traces. The approximately 30% packing fraction compared to high-density designs achieving packing fractions exceeding 60% facilitates automated assembly processes, provides tolerance for dimensional variations, and reduces mechanical stress from thermal expansion mismatches. The gap spacing of approximately 1.4 mm, representing approximately 70% of the pellet width dimension, is optimized to balance electrical isolation requirements, thermal expansion accommodation, and efficient utilization of module area.

According to certain embodiments, the P-type semiconductor material exhibits a Seebeck coefficient of approximately 210 μV/K, an electrical conductivity of approximately 1.4×10⁵ S/m, a thermal conductivity of approximately 1.2 W/(m·K), and a thermoelectric figure of merit (α²σ/κ) of approximately 5.2×10⁻³ K⁻¹. The N-type semiconductor material exhibits a Seebeck coefficient of approximately −170 μV/K, an electrical conductivity of approximately 1.655×10⁵ S/m, a thermal conductivity of approximately 1.2 W/(m·K), and a thermoelectric figure of merit of approximately 4.0×10⁻³ K⁻¹. The combination of P-type and N-type semiconductor materials with the defined Seebeck coefficients, electrical conductivities, thermal conductivities, and figures of merit represents an optimized material system tailored to work synergistically with the eighteen-pair architecture to achieve efficient thermoelectric cooling for moderate thermal loads.

The disclosed design principle maintains exactly eighteen pellet pairs across different module sizes while proportionally scaling dimensional parameters. In one embodiment, a module with overall dimensions of approximately 20 mm×20 mm employs pellets with cross-sectional areas of approximately 2 mm×2 mm, heights of approximately 2 mm, gap spacings of approximately 1.4 mm, plate thicknesses of approximately 0.2 mm, and trace thicknesses of approximately 0.05 mm. In an alternative embodiment, a module with overall dimensions of approximately 40 mm×40 mm employs pellets with cross-sectional areas of approximately 4 mm×4 mm, heights of approximately 4 mm, gap spacings of approximately 2.8 mm, plate thicknesses of approximately 0.4 mm, and trace thicknesses of approximately 0.1 mm. The scalable architecture maintains the dimensional ratios, electrical characteristics, and thermal performance characteristics across different physical footprints while preserving the eighteen-pair optimization.

Based on the images in the technical drawing, the thermoelectric cooler module exhibits a planar rectangular configuration wherein eighteen pairs of semiconductor pellets (totaling 36 individual pellets) are arranged between parallel top and bottom conductive plates. Each pellet pair comprises one P-type semiconductor pellet and one N-type semiconductor pellet positioned adjacent to each other. The pellets are distributed in a regular grid pattern across the surface area of the module, with consistent spacing maintained between adjacent pellets in both the horizontal and vertical directions. The top and bottom plates encapsulate the pellet array, with conductive traces on the inner surfaces of these plates forming electrical connections between pellets. The traces create a serpentine or zigzag electrical pathway that connects pellets of opposite polarity in series, such that current flows from the positive terminal through alternating P-type and N-type pellets to the neutral terminal.

The spatial relationship between pellets is characterized by uniform gap spacing that provides both electrical isolation and accommodation for thermal expansion. Each pellet has a substantially cuboid geometry with a square cross-sectional footprint and extends vertically between the top and bottom plates. The pellets are oriented with their longitudinal axes perpendicular to the plane of the conductive plates. The conductive traces route between pellet positions to electrically couple the top surface of one pellet to the bottom surface of an adjacent pellet of opposite polarity, creating the series electrical connection throughout the array. The overall geometric arrangement results in a compact, planar thermoelectric device wherein the pellet array occupies a central active region with the positive and neutral terminals positioned at opposing locations along the perimeter of the module to facilitate external electrical connection.

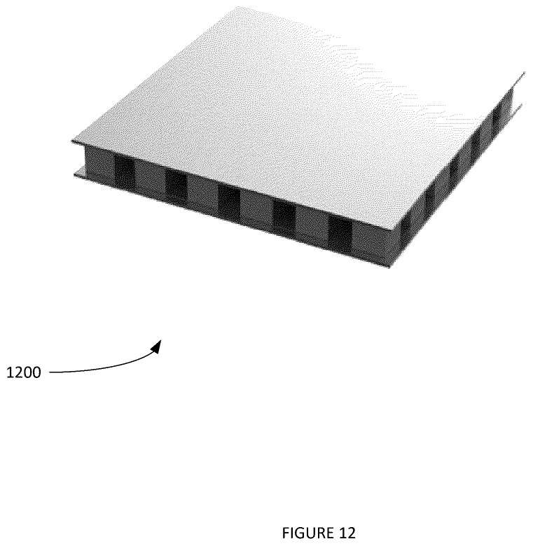

FIG. 12 illustrates an isometric view of a thermoelectric cooler module 1200 in an assembled configuration, according to some embodiments. The thermoelectric cooler module 1200 comprises a first electrically conductive plate forming the top surface of the module, visible in the isometric perspective. The module 1200 exhibits a substantially rectangular planar geometry with a thin profile characteristic of solid-state thermoelectric devices.

The exposed edge of the thermoelectric cooler module 1200 reveals the internal layered construction, wherein a plurality of semiconductor pellets are disposed between the first electrically conductive plate and a second electrically conductive plate (not visible in this view but parallel to and beneath the first plate). The semiconductor pellets appear as alternating elements along the visible edge, with individual pellets separated by gaps. Each semiconductor pellet extends vertically between the first electrically conductive plate and the second electrically conductive plate, with the pellets oriented such that their longitudinal axes are substantially perpendicular to the plane of the first and second plates.

The semiconductor pellets visible in the cross-sectional edge view include both P-type semiconductor pellets and N-type semiconductor pellets arranged in an alternating series configuration. The gaps between adjacent semiconductor pellets provide electrical isolation and accommodate thermal expansion during operation. The first electrically conductive plate has a uniform thickness and encapsulates the upper surfaces of the semiconductor pellets, while conductive traces (not visible but disposed on the inner surface of the first plate) electrically couple the pellets in series.

The thermoelectric cooler module 1200 demonstrates the compact, planar architecture of the disclosed device, with the overall module height determined by the combined thicknesses of the first electrically conductive plate, the semiconductor pellets, and the second electrically conductive plate. The thin profile of the module 1200 is achieved through precise control of pellet height and plate thickness parameters, enabling integration into space-constrained applications requiring solid-state thermal management.

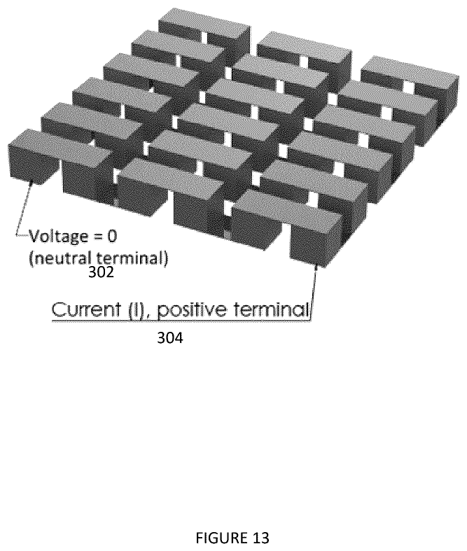

FIG. 13 illustrates an isometric view of the semiconductor pellet array 1300 with the first and second electrically conductive plates removed to reveal the internal structure and electrical configuration of the thermoelectric cooler module, according to some embodiments. The figure shows a plurality of semiconductor pellets arranged in a rectangular grid pattern, with the pellets organized in multiple rows and columns. The semiconductor pellets include P-type semiconductor pellets and N-type semiconductor pellets arranged in alternating pairs, with the P-type pellets depicted in a lighter orange/coral color and the N-type pellets depicted in a darker brown color.

The electrical configuration is illustrated through the identification of a neutral terminal 302 and a positive terminal 304. The neutral terminal 302 is labeled as “Voltage=0 (neutral terminal)” and is positioned at one corner of the pellet array. The positive terminal 304 is labeled as “Current (I), positive terminal” and is positioned at an opposite corner of the pellet array. The series electrical connection between the semiconductor pellets creates a continuous electrical path from the positive terminal 304 through the alternating P-type and N-type pellets to the neutral terminal 302. When electric current flows from the positive terminal 304 to the neutral terminal 302, thermoelectric cooling occurs at the junctions between the semiconductor pellets and the conductive traces that would be disposed on the inner surfaces of the first and second electrically conductive plates. The gaps between adjacent pellets are clearly visible, providing electrical isolation between pellets of the same polarity and accommodating thermal expansion during operation. The rectangular grid arrangement demonstrates the spatial distribution of the eighteen pairs of semiconductor pellets across the active area of the thermoelectric cooler module.

The thermoelectric cooler module 1200 can be integrated into a thermal management system for portable temperature-controlled applications. In certain embodiments, the thermoelectric cooler module 1200 is coupled to an aluminum cooling chamber portable unit 200, wherein the aluminum cooling chamber portable unit 200 comprises an aluminum payload chamber configured to store temperature-sensitive materials. The thermoelectric cooler module 1200 is thermally coupled to a wall of the aluminum payload chamber such that a cold side surface of the thermoelectric cooler module 1200 interfaces with the aluminum wall to extract heat from the payload chamber interior.

The integration of the thermoelectric cooler module 1200 with the aluminum cooling chamber portable unit 200 can be accomplished through direct thermal coupling wherein one of the first or second electrically conductive plates of the thermoelectric cooler module 1200 is positioned in thermal contact with the aluminum payload chamber wall. A thermal interface material can be disposed between the thermoelectric cooler module 1200 and the aluminum wall to minimize thermal contact resistance and maximize heat transfer efficiency. The thermal interface material can comprise thermal grease, phase-change material, thermal pads, or graphite sheets that have thermal conductivities sufficient to facilitate efficient heat extraction from the aluminum payload chamber.

In one embodiment, the thermoelectric cooler module 1200 is mounted at an angular orientation relative to the aluminum payload chamber wall, wherein the module 1200 is positioned at a predetermined angle to optimize the radial distribution of cooling effect across the payload chamber surface. The angular mounting configuration can range from approximately 15 degrees to approximately 25 degrees relative to perpendicular orientation, with a preferred angle of approximately 20 degrees in certain implementations. The hot side surface of the thermoelectric cooler module 1200, opposite to the cold side interfacing with the aluminum payload chamber, is coupled to a heat dissipation system configured to reject the thermal energy extracted from the payload chamber plus the electrical power input to the module 1200.

The aluminum cooling chamber portable unit 200 can further comprise a closed-loop cooling system thermally coupled to the hot side of the thermoelectric cooler module 1200, wherein the closed-loop cooling system comprises fluid-carrying conduits containing a working fluid selected from water, antifreeze, or other heat transfer fluids. A pump circulates the working fluid through the conduits to transport heat away from the thermoelectric cooler module 1200 to a heat exchanger, wherein the heat exchanger dissipates thermal energy to ambient air through natural convection or forced air cooling with fan assistance. The integration of the thermoelectric cooler module 1200 into the aluminum cooling chamber portable unit 200 enables portable temperature-controlled storage applications including medical sample transport, pharmaceutical storage, and other applications requiring precise temperature control in compact, battery-powered devices.

In certain embodiments, the thermoelectric cooler is configured such that pellet count, pellet geometry, and inter-pellet spacing are selected as independent design variables within a constrained footprint to achieve targeted electrical and thermal performance envelopes. The disclosed eighteen-pair configuration represents one optimized operating point within a broader design space in which pellet count may be intentionally reduced below conventional expectations to achieve improved cost efficiency, reduced current demand, and enhanced manufacturability while maintaining sufficient cooling capacity for moderate thermal loads.

In some implementations, the reduced pellet count architecture provides improved robustness against localized pellet failure or interconnect degradation. Because the total electrical resistance of the module is distributed across fewer pellet pairs, the electrical current density within each pellet can be reduced relative to higher-density configurations operated at comparable cooling loads, thereby reducing electromigration risk, Joule heating, and long-term material degradation. This characteristic can improve operational lifetime under cyclic loading conditions commonly encountered in portable and battery-powered applications.

In certain embodiments, the thermoelectric cooler module is configured such that the pellet arrangement produces a substantially uniform areal heat flux at the cold-side interface despite the reduced pellet population. The conductive plates act as lateral heat spreaders, redistributing localized heat absorption associated with individual pellet junctions across the full plate area. This plate-level thermal spreading enables effective coupling to downstream cold plates, chamber walls, or structural members without requiring a one-to-one correspondence between pellet locations and cooled surface features.

In some embodiments, the thermoelectric cooler is configured to operate within a defined electrical operating envelope that limits peak current density to reduce parasitic resistive losses. The reduced pellet count architecture enables operation at lower absolute current levels for a given cooling load relative to higher-density designs, thereby improving compatibility with low-voltage power sources, including lithium-based battery packs, supercapacitors, or regulated DC power supplies. This electrical characteristic supports autonomous and mobile deployments where power availability is constrained.

In certain implementations, the thermoelectric cooler module is coupled to a controller configured to dynamically regulate drive current based on sensed temperature conditions. One or more temperature sensors can be positioned at the cold-side interface, within the payload chamber, or at the hot-side heat rejection interface. The controller can modulate current amplitude, duty cycle, or polarity in response to sensed temperature, enabling closed-loop temperature regulation, rapid pull-down operation, steady-state holding operation, or energy-saving maintenance modes.

In some embodiments, the reduced pellet architecture enables improved transient thermal behavior. The lower thermal mass associated with fewer semiconductor pellets can reduce the thermal inertia of the module, enabling faster response to changes in drive current. This can be advantageous in applications requiring rapid temperature stabilization, intermittent cooling cycles, or pulsed operation synchronized with payload loading or access events.

In certain embodiments, the thermoelectric cooler module is configured to tolerate mechanical and thermal stresses associated with transport and handling. The increased inter-pellet spacing provides compliance that accommodates differential thermal expansion between semiconductor pellets, conductive plates, and bonding materials. This structural compliance reduces shear stress at pellet-to-trace interfaces during thermal cycling, thereby improving mechanical reliability under repeated heating and cooling cycles.

In some implementations, the conductive plates include surface treatments or intermediate layers configured to improve adhesion, reduce interfacial thermal resistance, or inhibit diffusion between dissimilar materials. Such treatments can include nickel barrier layers, gold flash coatings, diffusion barrier films, or surface roughening processes that promote reliable bonding between pellets and conductive traces without materially affecting electrical routing or thermal performance.

In certain embodiments, the thermoelectric cooler module is configured for bidirectional thermal operation, such that reversal of electrical current direction causes the cold-side and hot-side interfaces to interchange roles. This bidirectional capability enables the same module to function as either a cooler or a heater, allowing temperature stabilization above or below ambient and enabling defrosting, conditioning, or thermal recovery modes within an integrated thermal management system.

In some embodiments, the reduced pellet architecture is intentionally selected to minimize acoustic and vibrational disturbances. Because the thermoelectric cooler operates without moving parts and can be paired with low-speed or intermittent heat rejection components, the system can achieve near-silent operation suitable for medical, laboratory, or consumer environments where noise and vibration are undesirable.

In certain implementations, the thermoelectric cooler module is configured to integrate mechanically and thermally with modular heat rejection assemblies, including liquid-cooled blocks, air-cooled fin stacks, or phase-change-assisted heat spreaders. The planar geometry and standardized plate surfaces facilitate repeatable mounting and interchangeability across different system configurations without requiring redesign of the thermoelectric module itself.

In some embodiments, the eighteen-pair thermoelectric cooler architecture is implemented as part of a scalable product family in which multiple modules can be operated independently or in parallel to achieve higher aggregate cooling capacity. Multiple modules can be distributed across a larger surface area, stacked in layered arrangements, or operated in staged configurations where different modules are activated sequentially to optimize power consumption and thermal stability.

In certain embodiments, the disclosed thermoelectric cooler design is particularly suited for regulatory-sensitive applications due to its solid-state operation and absence of refrigerants, pressurized vessels, or mechanically actuated components. This simplifies compliance with transportation, medical device, and environmental regulations while improving system reliability and safety.

Collectively, the disclosed embodiments establish a thermoelectric cooler architecture in which reduced pellet count, standardized pellet geometry, controlled spacing, and fixed external footprint cooperate to provide a cost-effective, reliable, and application-tuned cooling solution. The architecture departs from conventional high-density thermoelectric designs by recognizing that moderate thermal load applications benefit from deliberate reduction in junction density rather than maximization, thereby enabling new classes of portable, battery-powered, and maintenance-free thermal management systems.

CONCLUSION

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine accessible medium compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium.

1. A thermoelectric cooler module comprising:
a first electrically conductive plate;
a second electrically conductive plate arranged substantially parallel to the first electrically conductive plate and spaced apart therefrom by a predetermined distance;
a plurality of semiconductor pellet pairs disposed between the first electrically conductive plate and the second electrically conductive plate, wherein each semiconductor pellet pair comprises a P-type semiconductor pellet and an N-type semiconductor pellet;
a plurality of conductive traces disposed on surfaces of the first electrically conductive plate and the second electrically conductive plate, wherein the conductive traces electrically couple the semiconductor pellet pairs in series to form a continuous electrical path;
a positive terminal electrically coupled to the continuous electrical path; and
a neutral terminal electrically coupled to the continuous electrical path; wherein adjacent semiconductor pellets are separated by gaps of predetermined width to provide electrical isolation and accommodate thermal expansion.

2. The thermoelectric cooler module of claim 1, wherein the plurality of semiconductor pellet pairs comprises exactly eighteen (18) pairs of semiconductor pellets.

3. The thermoelectric cooler module of claim 2, wherein the thermoelectric cooler module is configured to provide cooling for thermal loads in a range of approximately 5 to 30 Watts per square centimeter.

4. The thermoelectric cooler module of claim 2, wherein each semiconductor pellet has a cross-sectional area of approximately 2 mm×2 mm and a height of approximately 2 mm, establishing an aspect ratio of approximately 1:1.

5. The thermoelectric cooler module of claim 4, wherein the gaps between adjacent semiconductor pellets have a width of approximately 1.4 mm.

6. The thermoelectric cooler module of claim 5, wherein the gap width of approximately 1.4 mm represents approximately 70% of a pellet width dimension.

7. The thermoelectric cooler module of claim 4, wherein the plurality of semiconductor pellet pairs occupies a pellet packing fraction of approximately 30% within a total module volume.

8. The thermoelectric cooler module of claim 2, wherein the P-type semiconductor pellet exhibits a Seebeck coefficient of approximately 210 μV/K, an electrical conductivity of approximately 1.4×10⁵ S/m, a thermal conductivity of approximately 1.2 W/(m·K), and a thermoelectric figure of merit of approximately 5.2×10⁻³ K⁻¹.

9. The thermoelectric cooler module of claim 8, wherein the N-type semiconductor pellet exhibits a Seebeck coefficient of approximately −170 μV/K, an electrical conductivity of approximately 1.655×10⁵ S/m, a thermal conductivity of approximately 1.2 W/(m·K), and a thermoelectric figure of merit of approximately 4.0×10⁻³ K⁻¹.

10. The thermoelectric cooler module of claim 2, wherein the thermoelectric cooler module has overall planar dimensions of approximately 20 mm×20 mm.

11. The thermoelectric cooler module of claim 10, wherein the first electrically conductive plate and the second electrically conductive plate each have a thickness of approximately 0.2 mm.

12. The thermoelectric cooler module of claim 11, wherein the conductive traces have a thickness of approximately 0.05 mm.

13. The thermoelectric cooler module of claim 2, wherein the eighteen pairs of semiconductor pellets are arranged in a rectangular grid pattern selected from a group consisting of a 3×6 configuration, a 2×9 configuration, and a 4×4.5 staggered configuration.

14. The thermoelectric cooler module of claim 2, wherein the P-type semiconductor pellet and the N-type semiconductor pellet comprise bismuth telluride (Bi₂Te₃) or bismuth telluride alloys.

15. The thermoelectric cooler module of claim 2, further comprising an aluminum cooling chamber portable unit thermally coupled to the first electrically conductive plate or the second electrically conductive plate, wherein the aluminum cooling chamber portable unit comprises an aluminum payload chamber configured to store temperature-sensitive materials, and wherein the thermoelectric cooler module is positioned to extract heat from the aluminum payload chamber.
